(19) United States
(12) Patent Application Publication
(10) Pub. No.: US 2009/0067129 A1
(43) Pub. Date: Mar. 12, 2009

(54) CONSTANT TEMPERATURE BURST-ISOLATION CABINET

(76) Inventor: Zhenghao Shen, Jiangsu (CN)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 12/298,226

(22) PCT Filed: Mar. 12, 2007
(86) PCT No.: PCT/CN07/00788

§ 371 Date: Oct. 23, 2008

(30) Foreign Application Priority Data
Apr. 26, 2006 (CN) 200610040092.1

(51) Int. Cl. H05K 7/20

(52) U.S. Cl. 361/691

(57) ABSTRACT

A constant-temperature burst-isolation cabinet includes body of cabinet (4), the characters are that the cabinet also includes an air temperature regulator, indoor unit and the outdoor unit of the regulator are installed inside and outside the cabinet (4). Mounting hole for interface is prepared on lateral wall of the cabinet (4), explosion suppression interface (17) is inside mounting hole for the interface. Through throttle decompression element (18), explosion suppression interface (17), and pipe (16), evaporator (8) inlet of indoor unit is connected to condenser (10) outlet of outdoor unit. Through explosion suppression interface (17), and pipe (16), evaporator (8) outlet of indoor unit is connected to compressor (14) inlet of outdoor unit, and through pipe (16), compressor (14) outlet of outdoor unit is connected to condenser (10) inlet. The throttle decompression element (18) is expansion valve or capillary. By using the constant-temperature burst-isolation cabinet, not easy of aged deterioration of heating element, realizes the thermostatic control for air temperature of electric apparatus, and insures the normal working of electric apparatus. The invention is suitable to explosion suppression of heating element in dangerous place such as combustible, explosive places.

### CROSS-REFERENCE TO RELATED APPLICATION

This application claims priority to PCT Application No. PCT/CN2007/000788, filed Mar. 12, 2007 and entitled “CONSTANT TEMPERATURE BURST-ISOLATION CABINET”, which also claims priority to Chinese Patent Application No. 200610040092.1, filing date Apr. 26, 2006, which is incorporated by reference herein its entirety.

### FIELD OF THE INVENTION

The present invention relates to a burst-isolation apparatus, in particular to a constant temperature burst-isolation cabinet designed to accommodate the heating units (heating elements) on electric apparatuses such as converter, soft starter, power module, thyristor, capacitor and resistor, etc., and is applicable to burst isolation for heating units (heating elements) in an inflammable or explosive environment.

### BACKGROUND OF THE INVENTION

It is well-known that a burst-isolation cabinet is designed to accommodate the heating units (heating elements) on converter, soft starter, power module, thyristor, capacitor, and resistor, etc. for some electric apparatuses in an inflammable or explosive environment. The burst-isolation cabinet is airtight. Since the burst-isolation cabinet is airtight and isolated from the external environment, the temperature of its inside heating units (heating elements) will become higher during operation and thereby its inside air temperature will increase. If the inside air temperature exceeds the working temperature of the heating units (heating elements), the heating units (heating elements) may be aged, damaged, and have shorter service life, and the electric apparatuses won't able to operate normally. Therefore, the air temperature inside the burst-isolation cabinet must be lowered with all efforts.

At present, there are usually two methods for lowering the air temperature inside burst-isolation cabinet: one method is to mount radiation fins on the external surface of the burst-isolation cabinet to increase the dissipation area of the cabinet, and blow the cabinet with a blower to force heat dissipation, so as to lower the air temperature inside the cabinet. Such a method can only solve the problem of heat dissipation of the cabinet and lower the air temperature rise rate in the cabinet, but can't be directly used to cool the air in the cabinet; the other method is to mount thermotubes on the wall of the burst-isolation cabinet and attach the heating units (heating elements) in the cabinet to the wall where the thermotubes are mounted, so as to utilize the medium in the thermotubes to dissipate the heat of the cabinet.

Both of above methods employ the heat dissipation mechanism to reduce the temperature of the cabinet. Though the air temperature rise rate in the cabinet can be lowered by heat dissipation of the cabinet, the air temperature inside the cabinet will rise slowly as time went by. When the air temperature in the cabinet rises and exceeds the working temperature of the heating units (heating elements), the electric apparatuses will still be unable to operate normally.

### SUMMARY OF THE INVENTION

The object of the present invention is to provide a constant temperature burst-isolation cabinet. With such a constant temperature burst-isolation cabinet, the heating units (heating elements) of the electric apparatuses will not be aged or damaged easily and have longer service life, and the air temperature inside the cabinet will be controlled at a constant value, so as to ensure normal operation of the electric apparatuses.

### In Order to Solve Above Problems, the Present Invention Employs the Following Technical Scheme:

The constant temperature burst-isolation cabinet provided in the present invention comprises a cabinet; wherein, the constant temperature burst-isolation cabinet further comprises an air temperature regulator, and the indoor unit and outdoor unit of the air temperature regulator are respectively mounted inside and outside of the cabinet. A mounting hole for interface is prepared on a side wall of the cabinet, and an explosion suppression interface is arranged in the mounting hole for interface. An evaporator inlet of the indoor unit is connected to a condenser outlet of the outdoor unit through a throttle decompression element, the explosion suppression interface, and a pipe. The evaporator outlet of the indoor unit is connected to the compressor inlet of the outdoor unit through the explosion suppression interface and a pipe, and the compressor outlet of the outdoor unit is connected to the condenser inlet through a pipe. Wherein, the throttle decompression element is an expansion valve or a capillary.

A partition is arranged in the cabinet, to form an explosion suppression chamber and a cooling chamber in the cabinet; an air channel and a mounting hole for blower are respectively arranged on both sides of the partition, and a blower is mounted in the mounting hole for blower. The evaporator in the indoor unit of the air temperature regulator is mounted in the cooling chamber. The condenser inlet of the outdoor unit is connected to the compressor outlet through a pipe, the compressor inlet is connected to the evaporator outlet through a pipe and the explosion suppression interface, and the condenser outlet is connected to the evaporator inlet through a pipe, the explosion suppression interface, and the throttle decompression element. A burst isolation blower is arranged on one side of the condenser.

A burst isolation cushion chamber is arranged outside of the cabinet, and the compressor is mounted on the top board of the burst isolation cushion chamber. A mounting hole for interface is prepared on the top board of the burst isolation cushion chamber, and an explosion suppression interface is mounted in the mounting hole for interface. The compressor inlet and the condenser outlet are respectively connected to the two explosion suppression interfaces on the walls of the cabinet through a pipe and an explosion suppression interface.

### The Above Scheme has the Following Advantages:

The constant temperature burst-isolation cabinet provided in the present invention comprises an air temperature regulator, and the indoor unit and outdoor unit of the air temperature regulator are respectively inside and outside of the cabinet. The evaporator inlet of the indoor unit is connected to the condenser outlet of the outdoor unit through a throttle decompression element and a pipe, the evaporator outlet is connected to the compressor inlet of the outdoor unit through a pipe, and the compressor outlet of the outdoor unit is connected to the condenser inlet through a pipe. Through the air temperature regulator, the air temperature inside the cabinet can be kept constant. Since the air temperature in the cabinet can be kept constant, the heating units (heating elements) of electric apparatuses (e.g., converter, soft starter, power module, thyristor, capacitor, and resistor) mounted in the cabinet can work in a constant-temperature working environment. Therefore, the heating units (heating element) will not be aged and damaged easily, the service life of the heating units (heating elements) will be longer, and the electric apparatuses can operate normally.

### DESCRIPTION OF FIGURES

FIG. 1 is a structural representation of the constant temperature burst-isolation cabinet provided in the present invention.

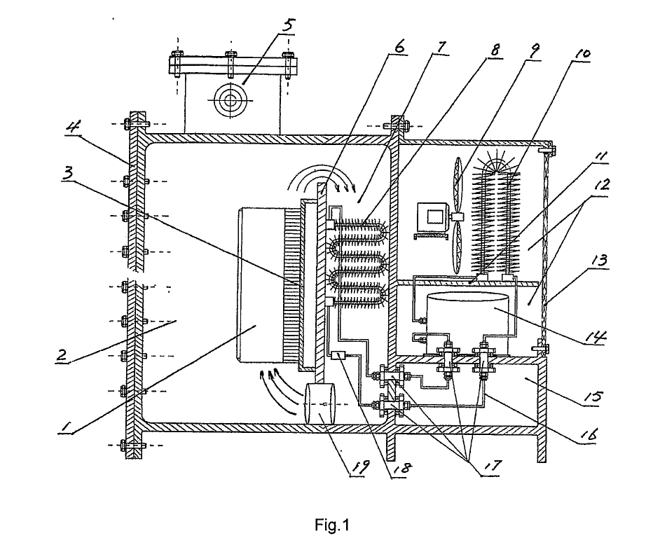

### DETAILED DESCRIPTION OF THE EMBODIMENTS

As shown in the figures, the constant temperature burst-isolation cabinet provided in the present invention comprises a cabinet 4 and an air temperature regulator. Wherein, the cabinet 4 is a airtight structure, with a partition 6 in it. The partition 6 is arranged vertically, and both of the vertical edges of the partition 6 are secured to the side walls of the cabinet 4 respectively, so that the cavity of the cabinet 4 is divided into two parts: one part serves as an explosion suppression chamber 2, and the other part serves as a cooling chamber 7. A support 3 is fixed to the side adjacent to the explosion suppression chamber 2, to mount the heating units (or heating elements) 1 of electric apparatuses such as converter, soft starter, power module, thyristor, capacitor, or resistor, etc. A terminal box 5 is arranged on the top of the cabinet 4; the terminal box is a burst-isolation box, which communicates with the cavity of the cabinet 4, to facilitate the connection between the heating units (1) and the electric apparatuses. A gap that serves as an air channel is arranged between the top edge of the partition 6 and the top board of the cabinet 4, so that the explosion suppression chamber 2 communicates with the cooling chamber 7. A mounting hole for blower is arranged between the bottom edge of the partition 6 and the bottom board of the cabinet 4, and a blower 19 is mounted in the mounting hole for blower. Wherein, the blower 19 is an axial blower, which forces the air to circulate through the explosion suppression chamber 2 and the cooling chamber 7. The air temperature regulator comprises an indoor unit and an outdoor unit, which are respectively mounted inside and outside of the cabinet 4. Wherein, the evaporator 8 of the indoor unit is mounted in the cooling chamber 7, and is fixed to the partition 6. Two mounting holes for interface are prepared on lower part of the cabinet wall adjacent to the evaporator 8, and an explosion suppression interface 17 is mounted in each of the mounting holes for interface. Wherein, the explosion suppression interface 17 is fitted to the corresponding mounting hole for interface in a sealed manner. The outdoor unit comprises a compressor 14 and a condenser 10, wherein, the inlet of the condenser 10 is connected to the outlet of the compressor 14 through a pipe 16, the inlet of the compressor 14 is connected to the outlet of the evaporator 8 through a pipe 16 and an explosion suppression interface 17, and the outlet of the condenser 10 is connected to the inlet of the evaporator 8 through a pipe 16, an explosion suppression interface 17, and a throttle decompression element 18. A burst isolation blower 9 is arranged at one side of the condenser 10. Wherein, the throttle decompression element 18 is an expansion valve or a capillary.

To facilitate installation, a burst isolation cushion chamber 15 and a heat dissipation area 12 are arranged in sequence from bottom to top on the outer side of the cabinet wall near one side of the cooling chamber 7; the burst isolation cushion chamber and the heat dissipation area form a box type structure in the same height as the cabinet 4, wherein, the burst isolation cushion chamber 15 is an airtight burst-isolation box, and the compressor 14 is mounted on the top board of the burst isolation cushion chamber 15. A surporter 11 is arranged in the middle of the heat dissipation area 12; the surporter 11 is a flat plate, arranged horizontally and integrated with the cabinet 4, and mounted in the middle of the heat dissipation area 12. The outer side wall of the heat dissipation area 12 is a protective mesh cover 13 which has leak. The condenser 10 and the burst-isolation blower 9 are mounted on the surporter 11; wherein, the burst-isolation blower 9 is mounted between the condenser 10 and the cabinet wall. Two mounting holes for interface are prepared on the top board of the burst isolation cushion chamber 15, and an explosion suppression interface 17 is mounted in each of the mounting holes for interface; in addition, the explosion suppression interface 17 is fitted to the mounting hole for interface in a sealed manner. The outlet of the evaporator 8 is connected to the inlet of the compressor 14 through a pipe 16, an explosion suppression interface 17 on the cabinet wall, a pipe 16, an explosion suppression interface 17 on the top board of the burst isolation cushion chamber 15, and a pipe 16; the outlet of the compressor 14 is connected to the inlet of the condenser 10 through a pipe 16. The inlet of the evaporator 8 is connected to the outlet of the condenser 10 through a throttle decompression element 18, a pipe 16, an explosion suppression interface 17 on the cabinet wall, a pipe 16, an explosion suppression interface 17 on the top board of the burst isolation cushion chamber 15, and a pipe 16. Wherein, the throttle decompression element 18 is an expansion valve or a capillary.

During operation, while the air in the cabinet 4 circulates under the driving force of the axial blower; the air temperature regulator lowers the air temperature in the cabinet 4 and keeps the air in the cabinet 4 at a constant temperature, so that the heating units (heating elements) 1 of the electric apparatuses (e.g., frequency converter, soft starter, power module, thyristor, capacitor, and resistor, etc.) are always in a constant-temperature working environment. Therefore, the heating units (heating element) 1 will not be aged and damaged easily, the service life of the heating units (heating elements) will be longer, and the electric apparatuses can operate normally.

1. A constant temperature burst-isolation cabinet, which comprises a cabinet (4); wherein, the constant temperature burst-isolation cabinet further comprises an air temperature regulator; the indoor unit and outdoor unit of the air temperature regulator are respectively inside and outside of the cabinet (4); mounting holes for interface are prepared on the side walls of the cabinet (4), and an explosion suppression interface (17) is mounted in the mounting holes for interface; the inlet of an evaporator (8) of the indoor unit is connected to the outlet of an condenser (10) of the outdoor unit through a throttle decompression element (18), an explosion suppression interface (17), and a pipe (16); the outlet of the evaporator (8) of the indoor unit is connected to the inlet of an compressor (14) of the outdoor unit through an explosion suppression interface (17) and a pipe (16); the outlet of the compressor (14) of the outdoor unit is connected to the inlet of the condenser (10) through a pipe (16).

2. The constant temperature burst-isolation cabinet according to claim 1, wherein, the throttle decompression element is an expansion valve.

3. The constant temperature burst-isolation cabinet according to claim 1, wherein, the throttle decompression element is a capillary.

4. The constant temperature burst-isolation cabinet according to claim 1, wherein, a partition (6) is arranged in the cabinet (4) to divide the cavity of the cabinet (4) into an explosion suppression chamber (2) and a cooling chamber (7); an air channel and a mounting hole for blower are arranged on each side of the partition (6) respectively, and a blower (19) is mounted in mounting hole for blower; the evaporator (8) of the indoor unit of the air temperature regulator is mounted in the cooling chamber (7); the inlet of the condenser (10) of the outdoor unit is connected to the outlet of the compressor (14) through a pipe (16), the inlet of the compressor (14) is connected to the outlet of the evaporator (8) through a pipe (16) and an explosion suppression interface (17), and the outlet of the condenser (10) is connected to the inlet of the evaporator (8) through a pipe (16), an explosion suppression interface (17), and a throttle decompression element (18); a burst-isolation blower (9) is mounted on the side of the condenser (10).

5. The constant temperature burst-isolation cabinet according to claim 4, wherein, a burst isolation cushion chamber (15) is arranged outside of the cabinet (4), and the compressor (14) is mounted on the top board of the burst isolation cushion chamber; an mounting hole for interface is prepared on the top board of the burst isolation cushion chamber (15), and an explosion suppression interface (17) is mounted in the mounting hole for interface; the inlet of the compressor (14) and the outlet of the condenser (10) are connected to the two explosion suppression interfaces (17) on the cabinet walls through a pipe (16) and a explosion suppression interface (17), respectively.

6. The constant temperature burst-isolation cabinet according to claim 1, wherein, a supporter (11) is arranged above the compressor, and the condenser (10) is mounted on the supporter.

7. The constant temperature burst-isolation cabinet according to claim 6, wherein, the supporter (11) is integrated with the walls of the cabinet (4).
